(19) United States
(12) Patent Application Publication
(10) Pub. No.: US 2019/0214974 A1
(43) Pub. Date: Jul. 11, 2019

(54) LATCH AND ISOLATION CIRCUIT

(71) Applicant: 2PAI SEMICONDUCTOR CO., LIMITED, Shanghai (CN)

(72) Inventor: Zhiwei DONG, Shanghai (CN)

(73) Assignee: 2PAI SEMICONDUCTOR CO., LIMITED, Shanghai (CN)

(21) Appl. No.: 16/002,949

(22) Filed: Jun. 7, 2018

(30) Foreign Application Priority Data
Jan. 10, 2018 (CN) 201810024553.9

(51) Int. Cl. H03K 3/356; H03K 3/288

(52) U.S. Cl. CPC H03K 3/356017; H03K 3/288

(57) ABSTRACT

A latch and an isolation circuit are provided. The latch includes a first-level substructure and at least one second-level substructure, the number of the at least one second-level substructure is k, and k is a positive integer greater than or equal to 1. The first-level substructure includes a first load having a first terminal coupled with a first port, a second load having a first terminal coupled with the first port, a first driving circuit having a control terminal coupled with a second terminal of the first load and a second terminal coupled with a second port, a second driving circuit having a control terminal coupled with a second terminal of the second load and a second terminal coupled with the second port. Each of the at least one second-level substructure includes a third load, a fourth load, a third driving circuit and a fourth driving circuit.

### CROSS REFERENCE OF RELATED APPLICATION

This application claims the benefit of priority to Chinese Patent Application No. 201810024553.9, titled “LATCH AND ISOLATION CIRCUIT”, filed on Jan. 10, 2018, the entire disclosure of which is incorporated herein by reference.

### FIELD

The present disclosure generally relates to electronic circuit technology field, and more particularly, to a latch and an isolation circuit.

### BACKGROUND

A latch is a level-sensitive memory device with a main function of latching a logic level of an input signal and maintaining it at a certain level (e.g. logic “0” or logic “1”) stably. Latches are widely applied to various circuits such as isolation circuits, memory circuits or the like.

In a common latch structure including a pair of inverters, two inverters are connected end to end, and each of the two inverters is comprised of a P-type Metal-Oxide-Semiconductor Field-Effect Transistor (MOSFET) and an N-type MOSFET. Specifically, as shown in FIG. 1, a latch 100 having a pair of inverter structure may include a first transistor MP1, a second transistor MN1, a third transistor MP2 and a fourth transistor MN2, where the first transistor MP1 and the second transistor MN1 constitute a first inverter (not shown), and the third transistor MP2 and the fourth transistor MN2 constitute a second inverter (not shown). In practical application, a source (and a substrate) of the first transistor MP1 and a source (and a substrate) of the third transistor MP2 may be connected with a power supply Vdd with a voltage of, for example, 3.3V or 1.8V, and a source (and a substrate) of the second transistor MN1 and a source (and a substrate) of the fourth transistor MN2 may be grounded to Vss generally with a potential of 0V. The latch 100 is a bistable latch having two latching points, one is an in-phase latching point A and the other is an inverting latching point B or vice versa. The logic levels latched by the two latching points are opposite to each other.

A flipping amplitude of a latch represents a voltage amplitude difference between a latched signal being recognized as logic “0” and a latched signal being recognized as logic “1”. The flipping amplitude of the latch 100 in the existing technology generally ranges from 0V to the power supply voltage Vdd, and the latch 100 with a flipping amplitude of 0V to the power supply voltage Vdd can satisfy the application requirements of majority circuits. However, with the continuous development of the integrated circuit technology, the requirements for chip area and process cost become higher and higher. The latch 100 with a flipping amplitude of 0V to the power supply voltage Vdd in the existing technology is gradually unable to meet the performance requirements of a high performance integrated circuit chip.

### SUMMARY

In order to reduce the flipping amplitude of the latches in the existing technologies, a latch is provided according to an embodiment of the present disclosure. The latch may include: a first-level substructure and at least one second-level substructure, where the number of the at least one second-level substructure is k, and k is a positive integer greater than or equal to 1; where the first-level substructure may include: a first load having a first terminal coupled with a first port, a second load having a first terminal coupled with the first port, a first driving circuit having a control terminal coupled with a second terminal of the first load and a second terminal coupled with a second port, and a second driving circuit having a control terminal coupled with a second terminal of the second load and a second terminal coupled with the second port; and each of the at least one second-level substructure may include: a third load, a fourth load, a third driving circuit and a fourth driving circuit; in a first second-level substructure, a first terminal of the third load is coupled with the second terminal of the second load, a second terminal of the third load is coupled with a control terminal of the third driving circuit, a first terminal of the first driving circuit and a first terminal of the fourth driving circuit, a first terminal of the fourth load is coupled with the second terminal of the first load, a second terminal of the fourth load is coupled with a control terminal of the fourth driving circuit, a first terminal of the second driving circuit and a first terminal of the third driving circuit, and a second terminal of the third driving circuit and a second terminal of the fourth driving circuit are coupled with a first reference port; and in an i-th second-level substructure, a first terminal of the third load is coupled with a second terminal of the fourth load of an (i−1)-th second-level substructure, a second terminal of the third load is coupled with a control terminal of the third driving circuit, a first terminal of a third driving circuit of the (i−1)-th second-level substructure and a first terminal of the fourth driving circuit, a first terminal of the fourth load is coupled with a second terminal of the third load of the (i−1)-th second-level substructure, a second terminal of the fourth load is coupled with a control terminal of the fourth driving circuit, a first terminal of the fourth driving circuit of the (i−1)-th second-level substructure and a first terminal of the third driving circuit, and a second terminal of the third driving circuit and a second terminal of the fourth driving circuit are coupled with an i-th reference port; where i is a positive integer greater than 1 and less than or equal to k.

In some embodiment, one or more of the first load, the second load, the third load and the fourth load may be resistors.

In some embodiment, the first driving circuit may include a first transistor, a control terminal of the first transistor may serve as the control terminal of the first driving circuit, a first terminal of the first transistor may serve as the first terminal of the first driving circuit, and a second terminal of the first transistor may serve as the second terminal of the first driving circuit; and the second driving circuit may include a second transistor, a control terminal of the second transistor may serve as the control terminal of the second driving circuit, a first terminal of the second transistor may serve as the first terminal of the second driving circuit, and a second terminal of the second transistor may serve as the second terminal of the second driving circuit.

In some embodiment, the first transistor and the second transistor may be N-type MOSFETs; the first port may be a power supply port, the power supply port may be configured to be input with a power supply voltage; a gate of the first transistor may be connected with the second terminal of the first load, a drain of the first transistor may be connected with a second terminal of the third load in a first second-level substructure, and a source of the first transistor may be connected with the second port; and a gate of the second transistor may be connected with the second terminal of the second load, a drain of the second transistor may be connected with the second terminal of the fourth load in the first second-level substructure, and a source of to the second transistor may be connected with the second port.

In some embodiment, the first transistor and the second transistor may be bipolar transistors; the first port may be a power supply port, and the power supply port may be configured to be input with a power supply voltage; a base of the first transistor may be connected with the second terminal of the first load, a collector of the first transistor may be connected with the second terminal of the third load in the first second-level substructure, and an emitter of the first transistor may be connected with the second port; and a base of the second transistor may be connected with the second terminal of the second load, a collector of the second transistor may be connected with the second terminal of the fourth load in the first second-level substructure, and an emitter of the second transistor may be connected with the second port.

In some embodiment, the second port may be coupled with an output terminal of a current source.

In some embodiment, the first transistor and the second transistor may be P-type MOSFETs; the first port may be directly or indirectly coupled with a reference ground; a gate of the first transistor may be connected with the second terminal of the first load, a drain of the first transistor may be connected with the second terminal of the second load, and a source of the first transistor may be connected with the second port; and a gate of the second transistor may be connected with the second terminal of the second load, a drain of the second transistor may be connected with the second terminal of the first load, and a source of the second transistor may be connected with the second port.

In some embodiment, the second port may be coupled with an output terminal of a current source.

In some embodiment, the third driving circuit may include a third transistor, a control terminal of the third transistor may serve as the control terminal of the third driving circuit, a first terminal of the third transistor may serve as the first terminal of the third driving circuit, and a second terminal of the third transistor may serve as the second terminal of the third driving circuit; and the fourth driving circuit may include a fourth transistor, a control terminal of the fourth transistor may serve as the control terminal of the fourth driving circuit, a first terminal of the fourth transistor may serve as the first terminal of the fourth driving circuit, and a second terminal of the fourth transistor may serve as the second terminal of the fourth driving circuit.

In some embodiment, the first load and the second load have same or different electrical parameters, the first driving circuit and the second driving circuit have same or different electrical parameters, the third load and the fourth load have same or different electrical parameters, and the third driving circuit and the fourth driving circuit have same or different electrical parameters.

An isolation circuit is also provided according to embodiments of the present disclosure, where the isolation circuit may include the aforementioned latch.

In some embodiment, the isolation circuit may further include a main isolating capacitor, a voltage dividing capacitor and an amplifier; where a first terminal of the main isolating capacitor is coupled with an input terminal of the isolation circuit, and a second terminal of the main isolating capacitor is coupled with a first terminal of the voltage dividing capacitor and the control terminal of the first driving circuit; a second terminal of the voltage dividing capacitor is coupled with a ground terminal; the control terminal of the second driving circuit is coupled with an input terminal of the amplifier; and an output terminal of the amplifier is coupled with an output terminal of the isolation circuit.

Compared with the existing technology, the present disclosure has the following beneficial effects.

The latch according to embodiments of the present disclosure may include a first-level substructure and at least one second-level substructure, where the number of the at least one second-level substructure is k, k is a positive integer greater than or equal to 1, the first-level sub-structure may include a first load, a second load, a first driving circuit and a second driving circuit, and the second-level substructure may include a third load, a fourth load, a third driving circuit and a fourth driving circuit. In an i-th second-level substructure, a first terminal of the third load may be coupled with a second terminal of the fourth load of an (i−1)-th second-level substructure, a second terminal of the third load may be coupled with a control terminal of the third driving circuit, a first terminal of a third driving circuit of the (i−1)-th second-level substructure and a first terminal of the fourth driving circuit, a first terminal of the fourth load may be coupled with a second terminal of the third load of the (i−1)-th second-level substructure, a second terminal of the fourth load may be coupled with a control terminal of the fourth driving circuit, a first terminal of the fourth driving circuit of the (i−1)-th second-level substructure and a first terminal of the third driving circuit, and a second terminal of the third driving circuit and a second terminal of the fourth driving circuit may be coupled with an i-th reference port; where i is a positive integer greater than 1 and less than or equal to k. With the above circuit structure, when the latch includes the first-level substructure and a second-level substructure, a flipping amplitude may be determined based on electrical parameters (e.g. impedance values) of the first load, the second load, the third load and the fourth load and electrical parameters (e.g. output current magnitude) of the first driving circuit, the second driving circuit, the third driving circuit and the fourth driving circuit. Further, the flipping amplitude of the latch according to the embodiments of the present disclosure substantially depends on the impedance value of each load and the current of each driving circuit. Since the impedance value of each load and the current of each driving circuit may have a wide design range in practice, the flipping amplitude can be any value from several millivolts to several volts, and can be achieved at any temperature and on any production line based on the process level in the existing technology. In conjunction with the current development trend of integrated circuits, the flipping amplitude of the latch in the present disclosure can meet the performance requirements of high-performance integrated circuits (e.g. isolation circuits).

Further, an isolation circuit is also provided according to embodiments of the present disclosure, which may include the latch according to the embodiments of the present disclosure. Since the flipping amplitude of the latch in the present disclosure may be any value from several millivolts to several volts, the flip energy required to bring the latch into a steady state can be small, and a capacitance of the main isolating capacitor configured to transmit energy in the isolation circuit can be also small. Accordingly, a chip area of the isolation circuit and the cost can be reduced. In addition, a circuit for driving the main isolating capacitor and a circuit for processing a common-mode rejection current are simplified, which facilitates design and optimization of the system structure of the isolation circuit.

### BRIEF DESCRIPTION OF THE DRAWINGS

FIG. 1 schematically illustrates a circuit diagram of a latch 100 in an existing technology;

FIG. 2 schematically illustrates a circuit diagram of another latch 200 in the existing technology;

FIG. 3 schematically illustrates a structural block diagram of a latch 300 according to an embodiment of the present disclosure;

FIG. 4 schematically illustrates a circuit diagram of a latch 400 according to an embodiment of the present disclosure;

FIG. 5 schematically illustrates a circuit diagram of a latch 500 according to another embodiment of the present disclosure;

FIG. 6 schematically illustrates a circuit diagram of a latch 600 according to another embodiment of the present disclosure;

FIG. 7 schematically illustrates a circuit diagram of a latch 700 according to another embodiment of the present disclosure; and

FIG. 8 schematically illustrates a circuit diagram of an isolation circuit 800 according to an embodiment of the present disclosure.

### DETAILED DESCRIPTION

As described in the background, a latch including a pair of inverting elements has a flipping amplitude of 0V to a power supply voltage, which can generally meet the application requirements of majority circuits. However, with the continuous development of integrated circuit technology, requirements for chip area and process cost become higher and higher. The latches with a flipping amplitude of 0V to a power supply voltage in the existing technology are gradually unable to meet the performance requirements of high-performance integrated circuit chips.

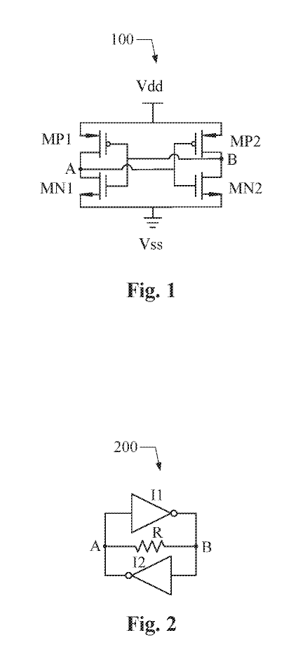

In order to reduce a flipping amplitude of a latch 100 shown in FIG. 1, another latch is provided in the existing technology, and the inventor of the present disclosure analyzes the existing latches. As shown in FIG. 2, the latch 200 may include a first inverter I1, a second inverter I2 and a resistor R, where the first inverter I1 and the second inverter I2 are connected end to end, and the resistor R is connected between an output terminal of the first inverter I1 and an output terminal of the second inverter I2. Each of the first inverter I1 and the second inverter I2 is comprised of a P-type Metal-Oxide-Semiconductor Field-Effect Transistor (MOSFET) and a N-type MOSFET (not shown), which is similar to the two inverters shown in FIG. 1 and will not be described in detail herein.

For simplification, it is assumed that electrical parameters of the first inverter I1 and electrical parameters of the second inverter I2 are the same, and in the first inverter I1, a transconductance of the P-type MOSFET operating in a saturation region is equal to a transconductance of the N-type MOSFET operating in a saturation region.

Further, an operating condition of the latch 200 is gₘ×R>2, where gₘ is the transconductance of the P-type MOSFET operating in the saturation region in the first inverter I1 or the transconductance of the N-type MOSFET operating in the saturation region in the second inverter I2, and R is a resistance value of the resistor R. V_{A} and V_{B} are respectively set to be voltage amplitudes of two latching points A and B in the latch 200, V_{T} is a threshold voltage of the P-type MOSFET in the first inverter I1, or a threshold voltage of the N-type MOSFET in the second inverter I2, and Rds is a resistance value of the P-type MOSFET or a resistance value of the N-type MOSFET in a linear region. The P-type MOSFET or the N-type MOSFET enters from the saturation region to the linear region when V_{A}−V_{B}>V_{T}, and the operating condition of the latch 200 becomes gₘ×(Rds//R)≤2, where gₘ≈2/Rds, “Rds//R” represents Rds being connected in parallel with R, that is, (Rds×R)/(Rds+R). Therefore, V_{T} is the flipping amplitude of the latch 200.

In the existing integrated circuit processes, V_{T} is generally 0.7V or 0.3V but not a constant. As a result, the flipping amplitude of the latch 200 varies with different chips. In general, the circuit application requirements of the latch 200 can only be met when V_{T} is maintained stably around 50 mV.

The inventor further analyzes that, the smaller a flipping amplitude, the smaller a flipping energy required for a latch to enter a steady state, under a premise of a small parasitic capacitance. For example, when the latch is applied to an isolation circuit, energy of the isolation circuit is transmitted by its internal main isolating capacitor. The larger the flip energy consumed when the latch enters the steady state, the larger a capacitance of the main isolating capacitor, the larger an area of the chip carrying the isolation circuit, the higher the consumption cost, and the more complicated a circuit driving the main isolating capacitor and a circuit processing a common-mode rejection current. In addition, the isolated signal in the isolation circuit is generally attenuated at a predetermined ratio, for example, at a ratio of 30:1, and when the flipping amplitude of the latch is too large, there is a large difference between the attenuated flipping amplitude and the original flipping amplitude, which is not beneficial for system design. If the predetermined ratio of attenuation is reduced, the system design will become more complicated and the chip area will be increased. Therefore, an optimum approach for constructing an isolation circuit seems to be reducing a flipping amplitude of a latch.

Based on the above analysis and development trend of current integrated circuits, the flipping amplitudes of the aforementioned latches in the existing technology are too large to meet performance requirements of high-performance integrated circuits (e.g. isolation circuits).

In view of the above-mentioned technical problems, a latch having a flipping amplitude of any value between several millivolts and several volts is provided according to embodiments of the present disclosure, which can be achieved at any temperature and on any production line based on the process level in the existing technologies, so as to meet the performance requirements of high-performance integrated circuits (such as isolation circuits).

The foregoing objects, features and advantages of the present invention will become more apparent from the following detailed description of specific embodiments of the invention taken in conjunction with the accompanying drawings.

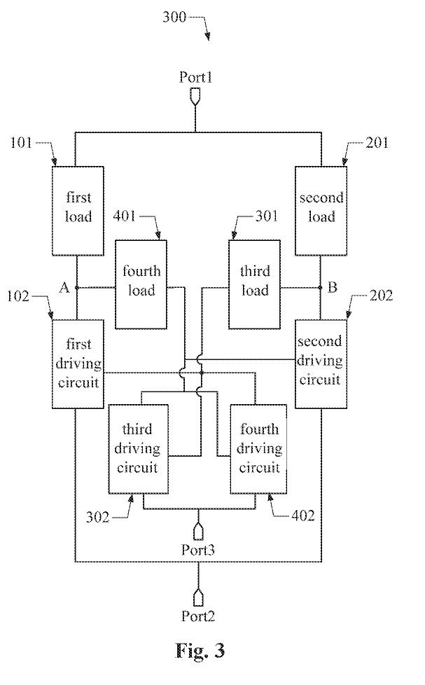

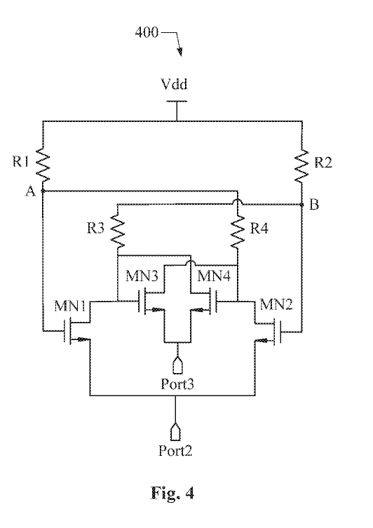

FIG. 3 schematically illustrates a structural block diagram of a latch 300 according to an embodiment of the present disclosure.

Referring to FIG. 3, the latch 300 may include a first-level substructure (now shown) and at least one second-level substructure (now shown), where the number of the at least one second-level substructure is k, and k is a positive integer greater than or equal to 1. For simplification, the latching 300 including a second-level substructure is shown in FIG. 3.

Specifically, the first-level substructure may include a first load 101, a second load 201, a first driving circuit 102 and a second driving circuit 202. Each of the at least one second-level substructure may include a third load 301, a fourth load 401, a third driving circuit 302 and a fourth driving circuit 402.

A first terminal of the first load 101 may be coupled with a first port Port1, a first terminal of the second load 201 may be coupled with the first port Port1, a control terminal A of the first driving circuit 102 may be coupled with a second terminal of the first load 101, a second terminal of the first driving circuit 102 may be coupled with a second port Port2, a control terminal B of the second driving circuit 202 may be coupled with a second terminal of the second load 201, and a second terminal of the second driving circuit 202 may be coupled with the second port Port2. The control terminal A of the first driving circuit 102 and the control terminal B of the second driving circuit 202 may serve as two latching points of the latch 300.

In a first second-level substructure, a first terminal of the third load 301 may be coupled with a second terminal of the second load 201, and a second terminal of the third load 301 may be coupled with a control terminal of the third driving circuit 302, a first terminal of the first driving circuit 102 and a first terminal of the fourth driving circuit 402, a first terminal of the fourth load 401 may be coupled with the second terminal of the first load 101, a second terminal of the fourth load 401 may be coupled with a control terminal of the fourth driving circuit 402, a first terminal of the second driving circuit 202 and a first terminal of the third driving circuit 302, and a second terminal of the third driving circuit 302 and a second terminal of the fourth driving circuit 402 may be coupled with a first reference port Port3.

In a second second-level substructure (not shown), a first terminal of the third load (not shown) is coupled with the second terminal of the fourth load 401 of the first second-level substructure, a second terminal of the third load may be coupled with a control terminal of the third driving circuit (not shown), a first terminal of the third driving circuit 302 of the first second-level substructure, and a first terminal of the fourth driving circuit (not shown), a first terminal of the fourth load is coupled with the second terminal of the third load 301 of the first second-level substructure, a second terminal of the fourth load is coupled with a control terminal of the fourth driving circuit, the first terminal of the fourth driving circuit 402 of the first second-level substructure and a first terminal of the third driving circuit, and a second of the third driving circuit and a second terminal of the fourth driving circuit may be coupled with a second reference port (not shown). A circuit connection relationship of a third second-level substructure and circuit connection relationships of even more second-level substructures may be derived by analogy, which will not be described in detail herein.

From above, it can be concluded that, in an i-th second-level substructure, wherein i is a positive integer greater than 1 and less than or equal to k, a first terminal of the third load may be coupled with a second terminal of the fourth load of an (i−1)-th second-level substructure, and a second terminal of the third load may be coupled with a control terminal of the third driving circuit, a first terminal of the third driving circuit of the (i−1)-th second-level substructure and a first terminal of the fourth driving circuit, a first terminal of the fourth load may be coupled with a second terminal of the third load of the (i−1)-th second-level substructure, a second terminal of the fourth load may be coupled with a control terminal of the fourth driving circuit, a first terminal of the fourth driving circuit of the (i−1)-th second-level substructure and a first terminal of the third driving circuit, and a second terminal of the third driving circuit and a second terminal of the fourth driving circuit may be coupled with an i-th reference port (not shown).

In some embodiment, the first load 101, the second load 201, the third load 301 and the fourth load 401 may be elements or devices with two terminals; and the first driving circuit 102, the second driving circuit 202, the third driving circuit 302 and the four driving circuit 402 may be elements or devices with three terminals. That is, the driving capabilities of the first driving circuit 102, the second driving circuit 202, the third driving circuit 302, and the fourth driving circuit 402 may be controlled by input parameters of their respective control terminals.

It should be noted that, the present disclosure imposes no limitation on the specific forms of the first port Port1, the second port Port2 and the i-th reference port, which may be any appropriate ports. In some embodiment, the first port Port1, the second port Port2 and the i-th reference port may be selected from a group of power supply ports, ground terminals, input/output ports of other functional circuits and other ports with potential values other than 0V.

In some embodiment, the first load 101, the second load 201, the third load 301 and the fourth load 401 may be any devices with current suppression capability. For example, one or more of the first load 101, the second load 201, the third load 301 and the fourth load 401 may be resistors, but are not limited thereto. For example, the first load 101, the second load 201, the third load 301 and the fourth load 401 may also be any of reactances and capacitances, or a combination thereof.

In some embodiment, each of the first driving circuit 102, the second driving circuit 202, the third driving circuit 302 and the fourth driving circuit 402 may be any device with current driving capability, such as an appropriate transistor or inverter, where the transistor may include a unipolar transistor also referred to as a field effect transistor, e.g. an N-type MOSFET or a P-type MOSFET), or a bipolar transistor referred to as a Bipolar Junction Transistor (BJT). The currents output by the first driving circuit 102, the second driving circuit 202, the third driving circuit 302 and the fourth driving circuit 402 may be determined based on a signal (for example, a voltage or current signal) applied to each terminal of the four driving circuits.

For simplification, in an embodiment of the present disclosure, the first load 101, the second load 201, the third load 301 and the fourth load 401 are resistors, and the first driving circuit 102, the second driving circuit 202, the third driving circuit 302 and the fourth driving circuit 402 are transistors.

Specifically, the first driving circuit 102 may include a first transistor (not shown), a control terminal of the first transistor may serve as the control terminal of the first driving circuit 102, a first terminal of the first transistor may serve as the first terminal of the first driving circuit 102, and a second terminal of the first transistor may serve as a second terminal of the first driving circuit 102. The second driving circuit 202 may include a second transistor (not shown), a control terminal of the second transistor may serve as the control terminal of the second driving circuit 202, a first terminal of the second transistor serves as the first terminal of the second driving circuit 202, and a second terminal of the second transistor may serve as the second terminal of the second driving circuit 202.

Specifically, the third driving circuit 302 may include a third transistor shown), control terminal of the third transistor may serve as the control terminal of the third driving circuit 302, a first terminal of the third transistor may serve as the first terminal of the third driving circuit 302, and a second terminal of the third transistor may serve as a second terminal of the third driving circuit 302. The fourth driving circuit 402 may include a fourth transistor (not shown), a control terminal of the fourth transistor may serve as the control terminal of the fourth driving circuit 402, a first terminal of the fourth transistor may serve as the first terminal of the fourth driving circuit 402, and a second terminal of the four transistor may serve as ti second terminal of the fourth driving circuit 402.

It should be understood by those skilled in the art that, the transistor is a device having three terminals. For a unipolar transistor, a control terminal of the unipolar transistor may be generally a gate, and a first terminal and a second terminal of the unipolar transistor may be a drain and a source respectively, or a source and a drain respectively. For a bipolar transistor, a control terminal of the bipolar transistor may be generally a base, and a first terminal and a second terminal of the bipolar transistor may be a collector and an emitter respectively, or an emitter and a collector respectively.

In some embodiment, the electrical parameters of the first load 101 and the second load 201 may be the same or different, the electrical parameters of the first driving circuit 102 and the second driving circuit 202 may be the same or different, the electrical parameters of the third load 301 and the fourth load 401 may be the same or different, and the electrical parameters of the third driving circuit 302 and the fourth driving circuit 402 may be the same or different.

Specifically, the electrical parameters of the first load 101 and the second load 201 are the same, the electrical parameters of the first driving circuit 102 and the second driving circuit 202 are the same, the electrical parameters of the third load 301 and the fourth load 401 are the same, and the electrical parameters of the third driving circuit 302 and the fourth driving circuit 402 are also the same. That is, preferably, the circuit structure and the electrical parameters of the latch 300 are symmetrical.

When the circuit structure and/or electrical parameters of the latch 300 are not completely symmetrical, there will be a gain factor between logic levels of the control terminal A of the first driving circuit 102 and the control terminal B of the second driving circuit 202 (i.e. the two latching points of the latch 300), where the gain factor depends on the electrical parameters (e.g. impedance values) of the first load 101, the second load 201, the third load 301 and the fourth load 401 and the electrical parameters (e.g. magnitude of output currents) of the first driving circuit 102, the second driving circuit 202, the third driving circuit 302, and the fourth driving circuit 402.

Based on the above circuit structure, when the latch 300 includes the first-level substructure and a second-level substructure, a flipping amplitude of the latch 300 may be determined based on the electrical parameters (e.g. impedance values) of the first load 101, the second load 201, the third load 301 and the fourth load 401 and the electrical parameters (e.g. magnitude of output currents) of the first driving circuit 102, the second driving circuit 202, the third driving circuit 302, and the fourth driving circuit 402. For simplification, in some embodiment, an impedance value of the first load 101 and an impedance value of the second load 201 may be equal and may be R1, a resistance value of the third load 301 and a resistance value of the fourth load 401 may be equal and may be R2, an output current of the first driving circuit 102 and an output current of the second driving circuit 202 may be equal and may be I1, and an output current of the third driving circuit 302 and an output current of the fourth driving circuit 402 may be equal and may be I2.

The flipping amplitude of the latch 300 according to embodiments of the present disclosure may be determined according to the impedance value R1 and magnitude of the current I2. Since R1 and I2 may have a wide design range, the flipping amplitude can be any value from several millivolts to several volts, and can be achieved at any temperature and on any production line based on the process level in the existing technology. With the development trend of integrated circuits, the flipping amplitude of the latch 300 can meet the performance requirements of high-performance integrated circuits such as an isolation circuit.

It should be noted that, when the latch 300 includes a first-level substructure and a plurality of second-level substructures, the method for calculating the flipping amplitude of the latch 300 may be appropriately adjusted, but the flipping amplitude can still be flexibly designed based on the wide design ranges of output currents of corresponding driving circuits.

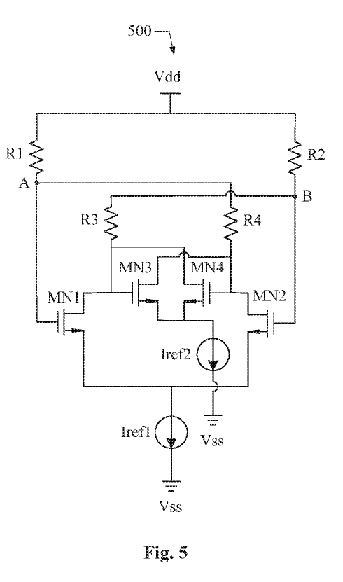

FIG. 4 schematically illustrates a circuit diagram of a latch 400 according to an embodiment of the present disclosure.

The circuit structure and operating principle of the latch 400 shown in FIG. 4 is basically similar to that of the latch 300 shown in FIG. 3. A main difference lies in that, in the latch 400, a first load, a second load, a third load and a fourth load may be resistors and are respectively labeled as R1, R2, R3 and R4. A first transistor, a second transistor, a third transistor and a fourth transistor may be N-type MOSFETs and are respectively labeled with MN1, MN2, MN3 and MN4.

Specifically, a first port (not shown) may be a power supply port (not shown), and the power supply port is configured to be input with a power supply voltage Vdd.

A gate A of the first transistor MN1 may be connected with a second terminal of first load R1, a drain of the first transistor MN1 may be connected with a second terminal of the third load R3 in the first second-level substructure, and a source of the first transistor MN1 may be connected with a second port Port2. A gate B of the second transistor MN2 may be connected with the second terminal of the second load R2, a drain of the second transistor MN2 may be connected with a second terminal of the fourth load R4 in the first second-level substructure, and a source of the second transistor MN2 may be connected with the second port Port2. The second port Port2 may be any appropriate port, for example, an input/output port of other functional circuits, or a port with an appropriate potential.

In the first second-level substructure, a gate of the third transistor MN3 may he connected with a drain of the first transistor MN1, a second end of the third load R3 and a drain of the fourth transistor MN4, and a source of the third transistor MN3 may be connected with a first reference port Port3. A gate of the fourth transistor MN4 may be connected with a drain of the second transistor MN2, a second terminal of the fourth load R4 and a drain of the third transistor, a source of the fourth transistor MN4 may be connected with the first reference port Port3. The first reference port Port3 may be any appropriate port, for example, an input/output port of other functional circuits, or a port with an appropriate potential.

The specific circuit structure and more information about the latch 400 including a plurality of second-level substructures may be derived by reference to the above description on the latch 300 shown in FIG. 3, which will not be described in detail herein.

FIG. 5 schematically illustrates a circuit diagram of a latch 500 according to another embodiment of the present disclosure.

The circuit structure and operating principle of the latch 500 shown in FIG. 5 is basically the same as that of the latch 400 shown in FIG. 4. A main difference lies in that, in the latch 500, the second port (not shown) may be coupled with an output terminal of a first current source Iref1, and an input terminal of the first current source Iref1 may be coupled with a ground terminal Vss. Further, the first current source Iref1 can provide a pull-down current (not shown) to the first transistor MN1 and the second transistor MN2, and when the second port is coupled with the first current source Iref1, the aforementioned I1 is the output current of the first current source Iref1.

Similarly, the first reference port (not shown) may be coupled with an output terminal of a second current source Iref2, and an input terminal of the second current source Iref2 may also be coupled with the ground terminal Vss. Further, the second current source Iref2 may provide a pull-down current (not shown) for the third transistor MN3 and the fourth transistor MN4 in the first second-level substructure, and when the first reference port is coupled with the second current source Iref2, the aforementioned I2 is the output current of the second current source Iref2.

It should be noted that, the present disclosure imposes no limitation on the circuit structures of the first current source Iref1 and the second current source Iref2, which may be any form of reference current source as long as the reference current source can provide a pull-down current.

More information about the latch 500 can be derived by reference to the above description on the latch 400 shown in FIG. 4, which will not be described in detail herein.

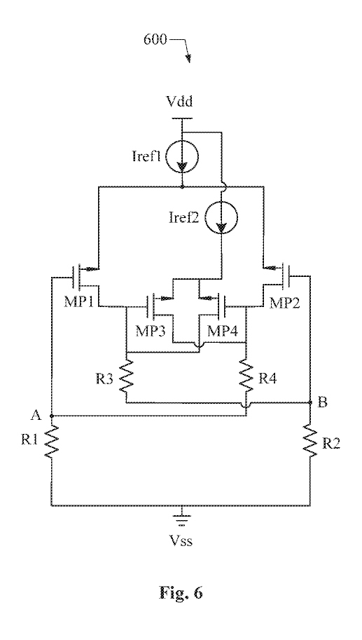

FIG. 6 schematically illustrates a circuit diagram of a latch 600 according to another embodiment of the present disclosure.

The circuit structure and operating principle of the latch 600 shown in FIG. 6 is basically the same as that of the latch 500 shown in FIG. 5. A main difference lies in that, in the latch 600, the first transistor, the second transistor, the third transistor and the fourth transistor may be P-type MOSFETs and are labeled as MP1, MP2, MP3 and MP4, respectively.

Specifically, the first port (not shown) may be directly or indirectly coupled with a reference ground Vss. In FIG. 6, the first port is directly coupled with the reference ground Vss. The second port (not shown) may be coupled with an output terminal of the first current source Iref1, an input terminal of the first current source Iref1 may be coupled with a power supply port (not shown), and the power supply port is configured to be input with a power supply voltage Vdd. The first reference port (not shown) may be coupled with an output terminal of the second current source Iref2, and an input terminal of the second current source Iref2 may be coupled with the power supply port. In the first second-level substructure, the first terminal of the third load R3 and the first terminal of the fourth load R4 may be indirectly coupled with the reference ground Vss.

A gate A of the first transistor MP1 may be connected with a second terminal of the first load R1, a drain of the first transistor MP1 may be connected with a second terminal of the third load R3 in the first second-level substructure, and a source of the first transistor MP1 may to be connected with the second port. A gate B of the second transistor MP2 may be connected with a second terminal of the second load R2, a drain of the second transistor MP2 may be connected with a second terminal of the fourth load R4 in the first second-level substructure, and a source of the second transistor MP2 may be connected with the second port.

In the first second-level substructure, a gate of the third transistor MP3 may be connected with the drain of the first transistor MP1, a second terminal of the third load R3, and a drain of the fourth transistor MP4 a source of the third transistor MP3 may be connected with the first reference port, a gate of the fourth transistor MP4 may be connected with a drain of the second transistor MP2, a second terminal of the fourth load R4, and the drain of the third transistor, and a source of the fourth transistor MP4 may be connected with the first reference port.

The specific circuit connection structure and more information on the latch 600 including a plurality of second-level substructures may be derived by reference to the above description on the latch 500 shown in FIG. 5, which will not be described in detail herein.

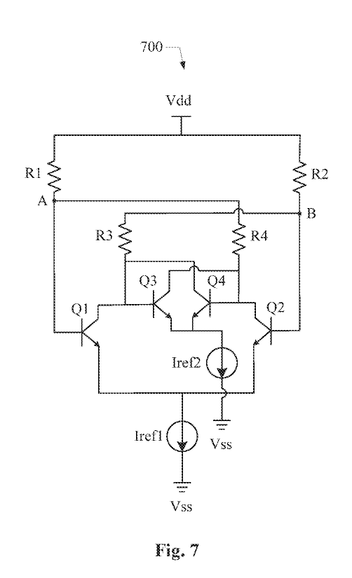

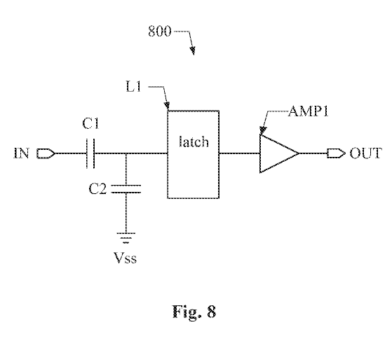

FIG. 7 schematically illustrates a circuit diagram of a latch 700 according to another embodiment of the present disclosure.

The circuit structure and operating principle of the latch 700 shown in FIG. 7 is basically the same as that of the latch 500 shown in FIG. 5. A main difference lies in that, the first transistor, the second transistor, the third transistor and the fourth transistor in the latch 700 may be bipolar transistors and denoted by Q1, Q2, Q3 and Q4 respectively.

Specifically, the first port (not shown) may be a power supply port (not shown), and the power supply port may be configured to be input with a power supply voltage Vdd.

A base A of the first transistor Q1 may be connected with a second terminal of the first load R1, a collector of the first transistor Q1 may be connected with a second terminal of the third load R3 in the first second-level substructure, and an emitter of the first transistor Q1 may be connected with the second port (not shown). In the embodiment shown in FIG. 7, the emitter of the first transistor Q1 is coupled with an output terminal of a first current source Iref1. A base B of the second transistor Q2 may be connected with a second terminal of the second load R2, a collector of the second transistor Q2 may be connected with a second terminal of the fourth load R4 in the first second-level substructure, and an emitter of the second transistor Q2 may be connected with the second port.

In the first second-level substructure, a base of the third transistor Q3 may be connected with a collector of the first transistor Q1, a second terminal of the third load R3 and a collector of the fourth transistor Q4. An emitter of the third transistor Q3 may be connected with a first reference port (not shown). In the embodiment shown in FIG. 7, the emitter of the third transistor Q3 may be connected with an output terminal of a second current source Iref2. A base of the fourth transistor Q4 may be connected with a collector of the second transistor Q2, a second terminal of the fourth load R4 and a collector of the third transistor, and an emitter of the fourth transistor Q4 may be connected with the first reference port.

The specific circuit structure and more information about the latch 700 including a plurality of second-level substructures may be derived by reference to the above description on the latch 400 shown in FIG. 4 and the latch 500 shown in FIG. 5, which will not be described in detail herein.

FIG. 8 schematically illustrates a circuit diagram of an isolation circuit 800 according to an embodiment of the present disclosure.

As shown in FIG. 8, the isolation circuit 800 may include a latch according to any of the embodiments shown in FIG. 3 to FIG. 7. Since the flipping amplitude of the latch in the present disclosure may be any value from several millivolts to several volts, the flipping energy required to bring the latch into a steady state may be small, and a capacitance of a main isolating capacitor C1 applied to transmit energy in the isolation circuit 800 is small. Accordingly, a chip area of the isolation circuit 800 and the cost can be both reduced. In addition, a circuit (not shown) for driving the main isolating capacitor C1 and a circuit (not shown) for processing a common-mode rejection current are simplified, which can facilitate design and optimization of the system structure of the isolation circuit 800.

As a non-limiting example, the isolation circuit 800 may include a main isolating capacitor C1, a voltage dividing capacitor C2, a latch L1 according to any of the embodiments shown in FIG. 3 to FIG. 7), and an amplifier AMP1.

A first terminal of the main isolating capacitor C1 may be coupled with an input terminal IN of the isolation circuit 800, and a second terminal of the main isolating capacitor C1 may be coupled with a first terminal of the voltage dividing capacitor C2 and a control terminal A of the first driving circuit 102 shown in FIG. 3. A second terminal of the voltage dividing capacitor C2 may be coupled with a ground terminal Vss, the control terminal B of the second driving circuit 202 shown in FIG. 3 may be coupled with an input terminal of the amplifier AMP1, and an output terminal of the amplifier AMP1 may be coupled with an output terminal OUT of the isolation circuit 800.

It should be noted that, in order to improve an anti-interference performance of the circuit, the isolation circuit 800 may also have a differential structure (not shown), that is, the isolation circuit 800 may be input with a differential signal. Correspondingly, the isolation circuit 800 may include two main isolating capacitors C1, two voltage dividing capacitors C2, and two latches L1, which will not be described in detail herein.

It should also be noted that, the terminology of “coupled” in the embodiments of the present disclosure refers to a direct connection or an indirect connection through other elements or devices.

Although the present disclosure is disclosed as above, the present disclosure is not limited thereto. Any person skilled in the art will be able to make various modifications and variations without departing from the spirit and scope of the disclosure, and the scope of the disclosure is therefore limited by the scope of the claims.

1. A latch, comprising:
a first-level substructure; and
at least one second-level substructure, the number of the at least one second-level substructure being k, and k being a positive integer greater than or equal to 1;
wherein the first-level substructure comprises:
a first load having a first terminal coupled with a first port;
a second load having a first terminal coupled with the first port;
a first driving circuit having a control terminal coupled with a second terminal of the first load and a second terminal coupled with a second port; and
a second driving circuit having a control terminal coupled with a second terminal of the second load and a second terminal coupled with the second port; and
wherein each of the at least one second-level substructure comprises: a third load, a fourth load, a third driving circuit and a fourth driving circuit;
wherein in a first second-level substructure, a first terminal of the third load is coupled with the second terminal of the second load, a second terminal of the third load is coupled with a control terminal of the third driving circuit, a first terminal of the first driving circuit and a first terminal of the fourth driving circuit, a first terminal of the fourth load is coupled with the second terminal of the first load, a second terminal of the fourth load is coupled with a control terminal of the fourth driving circuit, a first terminal of the second driving circuit and a first terminal of the third driving circuit, and a second terminal of the third driving circuit and a second terminal of the fourth driving circuit are coupled with a first reference port; and
wherein in an i-th second-level substructure, a first terminal of the third load is coupled with a second terminal of the fourth load of an (i−1)-th second-level substructure, a second terminal of the third load is coupled with a control terminal of the third driving circuit, a first terminal of the third driving circuit of the (i−1)-th second-level substructure and a first terminal of the fourth driving circuit, a first terminal of the fourth load is coupled with a second terminal of the third load of the (i−1)-th second-level substructure, a second terminal of the fourth load is coupled with a control terminal of the fourth driving circuit, a first terminal of the fourth driving circuit of the (i−1)-th second-level substructure and a first terminal of the third driving circuit, and a second terminal of the third driving circuit and a second terminal of the fourth driving circuit are coupled with an i-th reference port;
wherein i is a positive integer greater than 1 and less than or equal to k.

2. The latch according to claim 1, wherein one or more of the first load, the second load, the third load and the fourth load are resistors.

3. The latch according to claim 1, wherein the first driving circuit comprises a first transistor, a control terminal of the first transistor serves as the control terminal of the first driving circuit, a first terminal of the first transistor serves as the first terminal of the first driving circuit, and a second terminal of the first transistor serves as the second terminal of the first driving circuit; and
the second driving circuit comprises a second transistor, a control terminal of the second transistor serves as the control terminal of the second driving circuit, a first terminal of the second transistor serves as the first terminal of the second driving circuit, and a second terminal of the second transistor serves as the second terminal of the second driving circuit.

4. The latch according to claim 3, wherein
the first transistor and the second transistor are N-type MOSFETs;
the first port is a power supply port, and the power supply port is configured to be input with a power supply voltage;
a gate of the first transistor is connected with the second terminal of the first load, a drain of the first transistor is connected with a second terminal of the third load in a first second-level substructure, and a source of the first transistor is connected with the second port; and
a gate of the second transistor is connected with the second terminal of the second load, a drain of the second transistor is connected with the second terminal of the fourth load in the first second-level substructure, and a source of the second transistor is connected with the second port.

5. The latch according to claim 3, wherein the first transistor and the second transistor are bipolar transistors;
the first port is a power supply port, and the power supply port is configured to be input with a power supply voltage;
a base of the first transistor is connected with the second terminal of the first load, a collector of the first transistor is connected with the second terminal of the third load in the first second-level substructure, and an emitter of the first transistor is connected with the second port; and
a base of the second transistor is connected with the second terminal of the second load, a collector of the second transistor is connected with the second terminal of the fourth load in the first second-level substructure, and an emitter of the second transistor is connected with the second port.

6. The latch according to claim 4, wherein the second port is coupled with an output terminal of a current source.

7. The latch according to claim 5, wherein the second port is coupled with an output terminal of a current source.

8. The latch according to claim 3, wherein
the first transistor and the second transistor are P-type MOSFETs;
the first port is directly or indirectly coupled with a reference ground;
a gate of the first transistor is connected with the second terminal of the first load, a drain of the first transistor is connected with the second terminal of the second load, and a source of the first transistor is connected with the second port; and
a gate of the second transistor is connected with the second terminal of the second load, a drain of the second transistor is connected with the second terminal of the first load, and a source of the second transistor is connected with the second port.

9. The latch according to claim 8, wherein the second port is coupled with an output terminal of a current source.

10. The latch according to claim 1, wherein
the third driving circuit comprises a third transistor, a control terminal of the third transistor serves as the control terminal of the third driving circuit, a first terminal of the third transistor serves as the first terminal of the third driving circuit, and a second terminal of the third transistor serves as the second terminal of the third driving circuit; and
the fourth driving circuit comprises a fourth transistor, a control terminal of the fourth transistor serves as the control terminal of the fourth driving circuit, a first terminal of the fourth transistor serves as the first terminal of the fourth driving circuit, and a second terminal of the fourth transistor serves as the second terminal of the fourth driving circuit.

11. The latch according to claim 1, wherein the first load and the second load have same or different electrical parameters, the first driving circuit and the second driving circuit have same or different electrical parameters, the third load and the fourth load have same or different electrical parameters, and the third driving circuit and the fourth driving circuit have same or different electrical parameters.

12. An isolation circuit, comprising the latch according to claim 1.

13. The isolation circuit according to claim 12, further comprising: a main isolating capacitor, a voltage dividing capacitor and an amplifier;
wherein a first terminal of the main isolating capacitor is coupled with an input terminal of the isolation circuit, and a second terminal of the main isolating capacitor is coupled with a first terminal of the voltage dividing capacitor and the control terminal of the first driving circuit;
a second terminal of the voltage dividing capacitor is coupled with a ground terminal;
the control terminal of the second driving circuit is coupled with an input terminal of the amplifier; and
an output terminal of the amplifier is coupled with an output terminal of the isolation circuit.
